(19) United States
(12) Patent Application Publication
(10) Pub. No.: US 2011/0297435 A1
(43) Pub. Date: Dec. 8, 2011

(54) ENCLOSURE OF ELECTRONIC DEVICE

(75) Inventors: CHIEN-HUNG LIU, Tu-Cheng (TW); PO-CHUAN HSIEH, Tu-Cheng (TW); YU-CHANG PAI, Tu-Cheng (TW)

(73) Assignee: HON HAI PRECISION INDUSTRY CO., LTD., Tu-Cheng (TW)

(21) Appl. No.: 12/869,709

(22) Filed: Aug. 26, 2010

(30) Foreign Application Priority Data
Jun. 7, 2010 (TW) 99118301

(51) Int. Cl. H05K 9/00

(52) U.S. Cl. 174/383

(57) ABSTRACT

An enclosure includes a ventilation plate. The ventilation plate defines a number of through holes. Two hollow bulges extend from an edge bounding each of the through holes at two opposite sides of the plate. A top of each of the bulges defines an opening. The openings of the two bulges and the corresponding through hole define a passage for ventilation and elongate a path that electromagnetic signals must travel to pass through the ventilation plate. The enclosure can better shield the electronic device from EMI.

### CROSS-REFERENCE TO RELATED APPLICATIONS

Relevant subject matter is disclosed in the co-pending U.S. patent applications (Attorney Docket Nos. US32221, US32384, US32670, US32671, US32874, and US32875) having the same title and assigned to the same assignee as named herein.

### BACKGROUND

1. Technical Field

The present disclosure relates to an enclosure of an electronic device.

2. Description of Related Art

For the enclosure of a typical electronic device, electromagnetic interference (EMI) is a common problem during operation. Commonly, through holes are defined in the enclosure for aiding in heat dissipation, and though sizes and placement of the holes are chosen and arranged to help avoid EMI, problems from EMI still occur.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of a ventilation plate in an exemplary embodiment of an enclosure.

FIG. 2 is a sectional view of the ventilation plate of FIG. 1.

FIG. 3 is a graph showing EMI shielding effectiveness of a conventional enclosure and an enclosure using the plate in FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

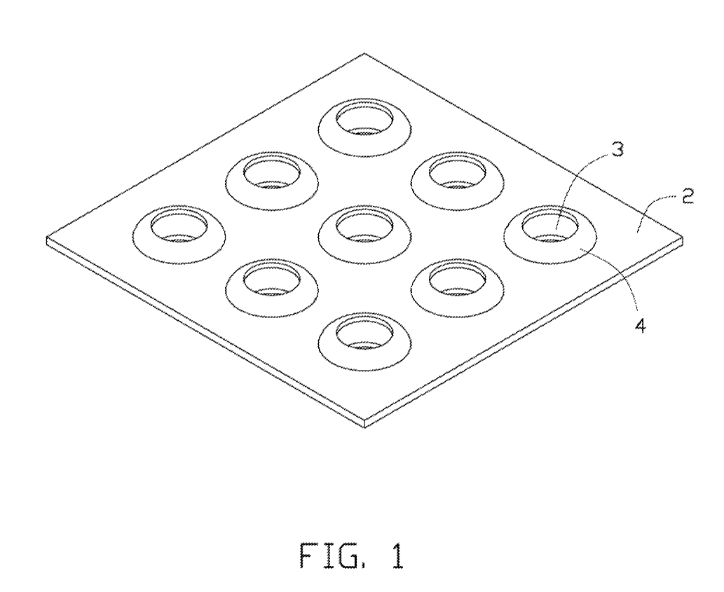

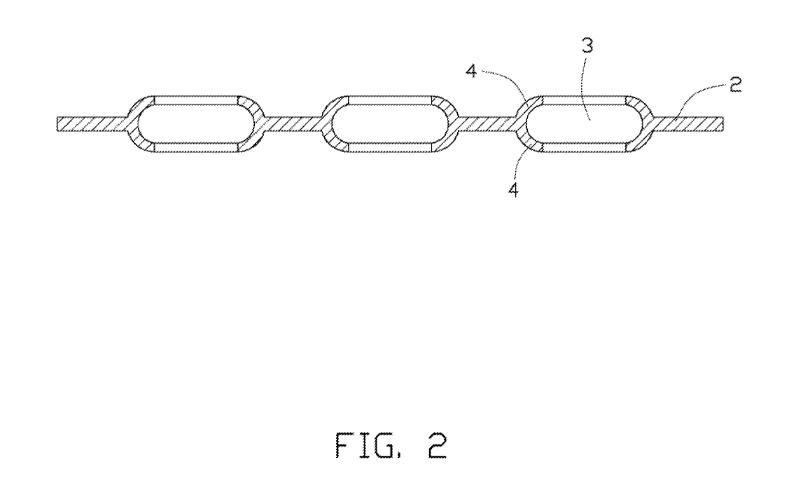

Referring to FIGS. 1 and 2, an exemplary embodiment of an enclosure of an electronic device includes a ventilation plate 2. The ventilation plate 2 can be arranged on a front side or a back side of the enclosure for ventilation.

The ventilation plate 2 defines a plurality of through holes 3. Two hollow bulges 4 extend from the edges bounding each through hole 3 at two opposite sides of the plate 2 respectively. A top of each of the bulges 4 defines an opening. The openings of the two bulges 4 and the corresponding through hole 3 define a passage for ventilation and elongate a path that electromagnetic signals must travel to pass through the ventilation plate 2. In the embodiment, each bulge 4 is a hemispherically curved surface. In other embodiments, each bulge 4 may be a hollow truncated cone.

The ventilation plate 2 can be integrally formed, or formed by pressing two metal sheets which have been punched with the bulges 4 at one side. The height of the two opposite bulges 4 elongates the passage electromagnetic signal must travel through the ventilation plate 2, thereby improving the EMI shielding effectiveness.

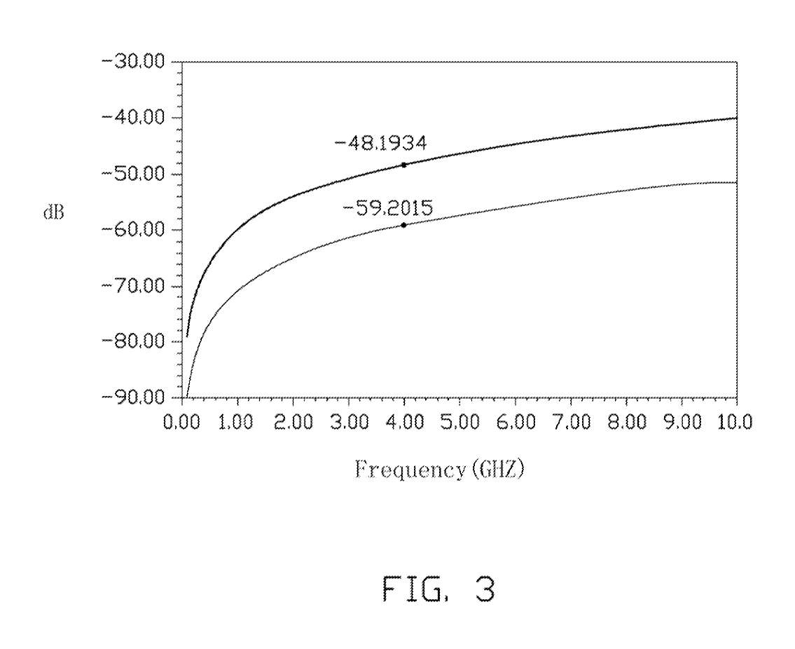

Referring to FIG. 3, a curve A1 represents EMI shielding effectiveness of a conventional enclosure. A curve A2 represents EMI shielding effectiveness of the enclosure using the plate 2 of FIG. 1. FIG. 3 clearly indicates that the EMI shielding effectiveness of the enclosure with the plate 2 is better than the EMI shielding effectiveness of the conventional enclosure.

In other embodiments, the size of the bulges 4 can be changed according to need. When the bulges 4 are configured with a different size, the EMI shielding effectiveness of the enclosure may be different. In addition, shape of the through holes 3 need not be round as shown in the figures.

The foregoing description of the embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. An electronic enclosure comprising a ventilation plate, wherein the ventilation plate defines a plurality of through holes, two hollow bulges extend from an edge bounding each of the through holes at two opposite sides of the plate, a top of each of the bulges defines an opening, the openings of the two bulges and the corresponding through hole defines a passage for ventilation and elongating a path that electromagnetic signals must travel to pass through the ventilation plate.

2. The enclosure of claim 1, wherein each of the through holes is round.

3. The enclosure of claim 2, wherein each of the bulges is a hollow truncated cone.

4. The enclosure of claim 2, wherein each bulge is a hemispherically curved surface with the opening.
